(19) United States
(12) Patent Application Publication
(10) Pub. No.: US 2026/0269170 A1
(43) Pub. Date: Sep. 10, 2026

(54) ABERRATION CORRECTOR, CHARGED PARTICLE BEAM DEVICE INCLUDING SAME, AND CONTROL METHOD FOR CONTROLLING SAME

(71) Applicant: Hitachi High-Tech Corporation, Tokyo (JP)

(72) Inventors: Hirokazu TAMAKI, Tokyo (JP); Yudai KUBO, Tokyo (JP)

(73) Assignee: Hitachi High-Tech Corporation, Tokyo (JP)

(21) Appl. No.: 19/160,954

(22) PCT Filed: Mar. 9, 2023
(86) PCT No.: PCT/JP2023/008955

§ 371 Date: Aug. 29, 2025

(51) Int. Cl. H01J 37/153; H01J 37/141; H01J 37/26

(52) U.S. Cl. CPC H01J 37/153; H01J 37/141; H01J 37/26; H01J 2237/1534

(57) ABSTRACT

An aberration corrector comprising a transfer lens disposed between a first multipole and a second multipole to control fourth-order coma aberration, includes: a first deflector, wherein the first and second multipoles generate a multipole field including a hexapole component, the first deflector adjusting at least one of: (i) the distance between the charged particle beam incident on the first multipole and the optical axis, and (ii) the azimuth angle of the beam incident on the first multipole; a second deflector adjusts at least one of: (i) the angle between the charged particle beam incident on an objective lens and the optical axis, and (ii) the azimuth angle of the beam incident on the objective lens; and a control unit configured to drive the first and second deflectors such that second-order coma aberration (B2) induced by the first deflector is at least partially cancelled by that induced by the second deflector.

### TECHNICAL FIELD

The present invention relates to a charged particle beam device, and more particularly to correction of a fourth-order coma aberration and a sixth-order coma aberration.

### BACKGROUND ART

A charged particle beam device such as a transmission electron microscope (TEM) or a scanning transmission electron microscope (STEM) is a device that generates an observation image of a specimen by illuminating the specimen with a charged particle beam. To improve the resolution of the observation image generated by the charged particle beam device, it is necessary to correct the aberration generated in the electron optical system.

PTL 1 discloses a STEM that calculates an autocorrelation function for each of a plurality of images obtained by changing a focus and that corrects a 2-fold astigmatism based on an aberration coefficient obtained by fitting an aberration function to an iso-intensity line of the autocorrelation function. It is also disclosed that a coma aberration can be measured by changing an incident angle of an electron beam to obtain a plurality of images instead of changing the focus.

### CITATION LIST

### Patent Literature

PTL 1: JP5188846A

### SUMMARY OF INVENTION

### Technical Problem

However, in PTL 1, a third-order or less aberration is to be corrected, and no consideration is given to controlling a fourth-order coma aberration. In an energy dispersive X-ray spectrometry (STEM-EDX) method for detecting fluorescent X-rays generated by electron beam illumination at the time of STEM observation, which is one of methods for generating an element distribution image of an observation specimen, it takes a long time to generate the element distribution image because the generation efficiency of fluorescent X-rays is low. To shorten the time required to generate the element distribution image without reducing the resolution, it is necessary to control the fourth-order coma aberration and the sixth-order coma aberration to maintain the diameter of the electron beam while widening the angle at which the electrons are captured and increasing the total amount of electron beam.

Therefore, an object of the invention is to provide an aberration corrector capable of controlling a fourth-order coma aberration or a sixth-order coma aberration, a charged particle beam device including the same, and a control method for controlling the same.

### Solution to Problem

To implement the above object, the invention is an aberration corrector in which a transfer lens is disposed between a first multipole and a second multipole, each of the first multipole and the second multipole forming a multipole field including a component of a hexapole field, the aberration corrector including: a first deflector configured to control at least one of a distance between a charged particle beam incident on the first multipole and an axis of an optical system and an azimuth angle of the charged particle beam incident on the first multipole; a second deflector configured to control at least one of a slope between a charged particle beam incident on an objective lens and the axis of the optical system and an azimuth angle of the charged particle beam incident on the objective lens; and a control unit configured to control the first deflector and the second deflector, in which the control unit executes first control executed on the first deflector and second control executed on the second deflector such that at least a part of a second-order coma aberration caused by the first control is canceled by a second-order coma aberration caused by the second control.

The invention is a charged particle beam device for generating an observation image of a specimen by illuminating the specimen with a charged particle beam, the charged particle beam device including: the above aberration corrector.

The invention is a control method for controlling an aberration corrector in which a transfer lens is disposed between a first multipole and a second multipole, the control method including: executing first control executed on a first deflector configured to control at least one of a distance between a charged particle beam incident on the first multipole and an axis of an optical system and an azimuth angle of the charged particle beam incident on the first multipole and second control executed on a second deflector configured to control at least one of a slope between a charged particle beam incident on an objective lens and the axis of the optical system and an azimuth angle of the charged particle beam incident on the objective lens such that at least a part of a second-order coma aberration caused by the first control is canceled by a second-order coma aberration caused by the second control.

### Advantageous Effects of Invention

According to the invention, an aberration corrector capable of controlling a fourth-order coma aberration and a sixth-order coma aberration, a charged particle beam device including the same, and a control method for controlling the same can be provided.

### BRIEF DESCRIPTION OF DRAWINGS

FIG. 1 is a diagram illustrating an example of an overall configuration of a charged particle beam device according to Embodiment 1.

FIG. 2A is a diagram illustrating an example of a configuration of an aberration corrector according to Embodiment 1.

FIG. 2B is a diagram illustrating an example of a first multipole.

FIG. 2C is a diagram illustrating an example of a second multipole.

FIG. 3A is a diagram illustrating control of a distance between a charged particle beam incident on the first multipole and an axis of an optical system.

FIG. 3B is a diagram illustrating control of an angle between a charged particle beam incident on an objective lens and the axis of the optical system.

FIG. 3C is a diagram illustrating an example of control of a fourth-order coma aberration (B4).

FIG. 3D is a diagram illustrating positions P0 to P4 of electron beams incident on the first multipole.

FIG. 3E is a diagram illustrating a pattern formed by the electron beam incident on the P0.

FIG. 3F is a diagram illustrating a pattern formed by the electron beam incident on the P1.

FIG. 3G is a diagram illustrating a pattern formed by the electron beam incident on the P2.

FIG. 3H is a diagram illustrating a pattern formed by the electron beam incident on the P3.

FIG. 3I is a diagram illustrating a pattern formed by the electron beam incident on the P4.

FIG. 4 is a diagram illustrating an example of a flow of processing according to Embodiment 1.

FIG. 5 is a diagram illustrating an example of an aberration adjustment screen.

FIG. 6A is a diagram illustrating another example of the aberration corrector.

FIG. 6B is a diagram illustrating another example of the aberration corrector.

FIG. 7A is a diagram illustrating an example of control of a sixth-order coma aberration (B6).

FIG. 7B is a diagram illustrating another example of the control of the sixth-order coma aberration (B6).

FIG. 7C is a diagram illustrating another example of the control of the sixth-order coma aberration (B6).

### DESCRIPTION OF EMBODIMENTS

Hereinafter, embodiments of a charged particle beam device according to the invention will be described with reference to the accompanying drawings. In the following description and the accompanying drawings, components having the same functional configuration are denoted by the same reference numerals, and redundant description thereof will be omitted.

### Embodiment 1

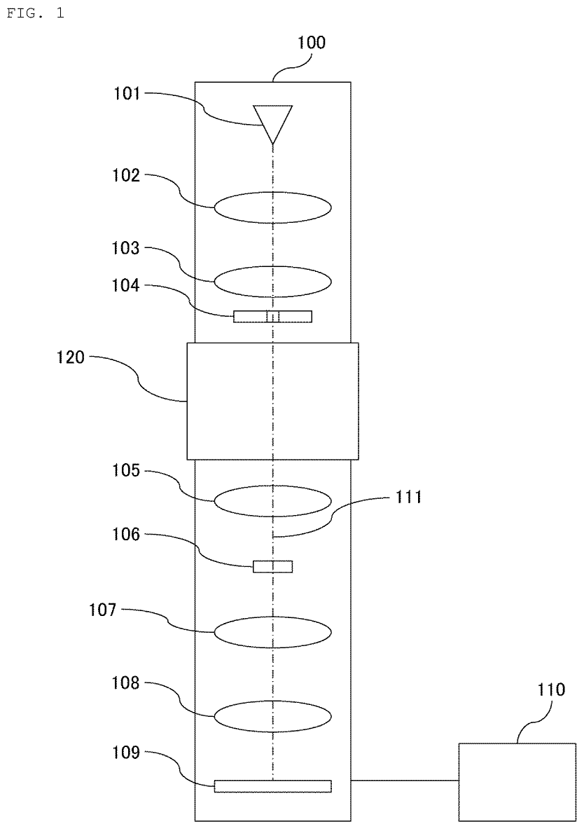

An example of an overall configuration of a scanning transmission electron microscope, which is one of charged particle beam devices, will be described with reference to FIG. 1. The scanning transmission electron microscope is a device that generates a transmission electron image by emitting a specimen with an electron beam and detecting transmission electrons transmitted through the specimen, and includes a lens body 100 and a control unit 110.

The control unit 110 is a device that controls units included in the lens body 100 and generates an observation image based on a detection signal transmitted from the lens body 100, and is implemented by, for example, a computer.

The lens body 100 includes an electron source 101, a condenser lens 102, a condenser lens 103, an aperture 104, an aberration corrector 120, an objective lens 105, an intermediate lens 107, a projection lens 108, and a detector 109. An axis of each of the condenser lens 102, the condenser lens 103, the aperture 104, the aberration corrector 120, the objective lens 105, the intermediate lens 107, the projection lens 108, and the detector 109 is aligned with an axis 111 of an optical system.

The electron source 101 emits an electron beam to illuminate a specimen 106. The emitted electron beam is accelerated by a predetermined acceleration voltage, is focused by the condenser lens 102 and the condenser lens 103, and passes through the aperture 104. The electron beam that has passed through the aperture 104 is corrected for aberration by the aberration corrector 120, and then is focused onto a surface of the specimen 106 by the objective lens 105. The electron beam transmitted through the specimen 106 is focused by the intermediate lens 107 and then projected onto the detector 109 by the projection lens 108. The detector 109 detects the projected electron beam and transmits the detection signal to the control unit 110. The control unit 110 generates the observation image based on the detection signal.

The scanning transmission electron microscope may further include an X-ray detector that detects fluorescent X-rays emitted from the specimen 106 when irradiated with the electron beam. The control unit 110 generates an element distribution image of the specimen 106 based on a detection signal from the X-ray detector.

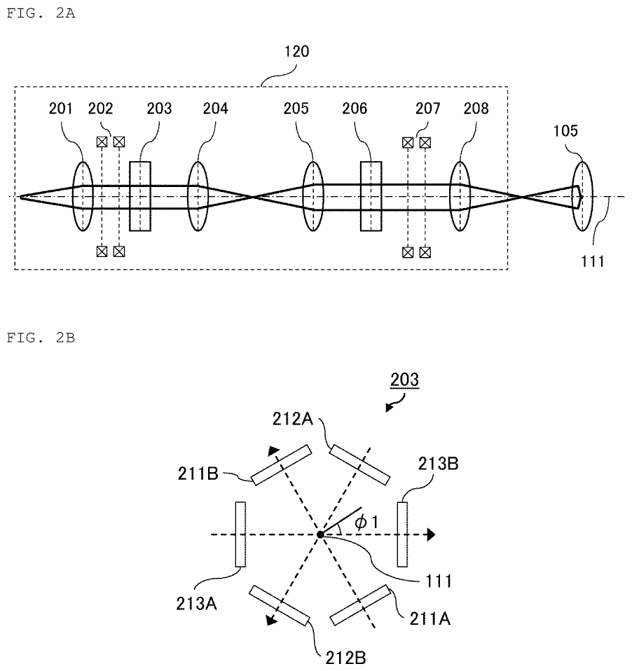

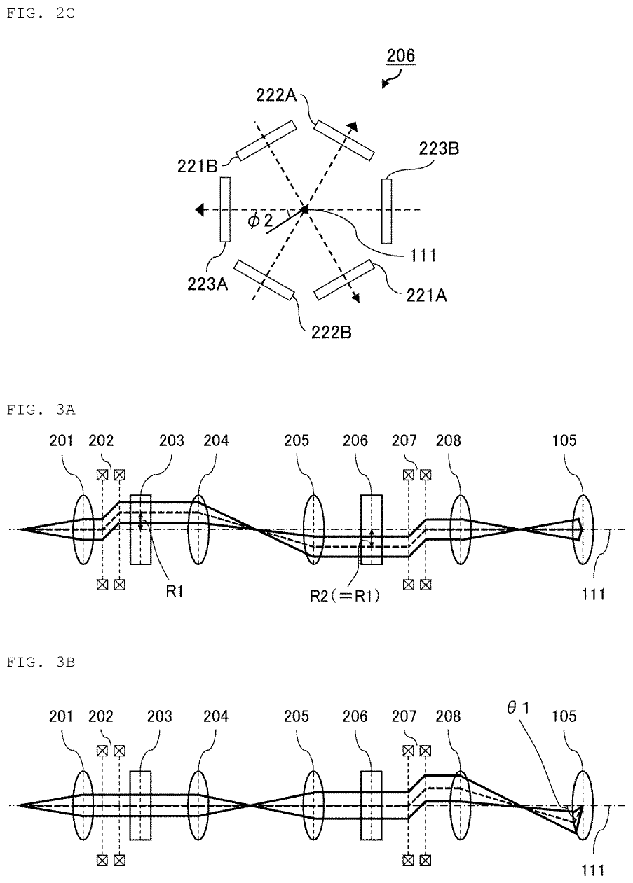

An example of a configuration of the aberration corrector 120 will be described with reference to FIG. 2A. The aberration corrector 120 includes an adjustment lens 201, a first deflector 202, a first multipole 203, a transfer lens 204, a transfer lens 205, a second multipole 206, a second deflector 207, and an adjustment lens 208. The transfer lens 204 and the transfer lens 205 are disposed between the first multipole 203 and the second multipole 206. The first multipole 203 and the second multipole 206 have a conjugate relationship due to the transfer lens 204 and the transfer lens 205.

The first multipole 203 and the second multipole 206 form a multipole field, which is a rotationally symmetric electric or magnetic field, in a region through which the electron beam passes. The first multipole 203 illustrated in FIG. 2B includes six magnetic poles 211A to 213B and forms a hexapole field, which is a three-fold symmetric field, by a flow of a magnetic flux between the magnetic poles. The second multipole 206 illustrated in FIG. 2C includes magnetic poles 221A to 223B and forms a hexapole field similarly to the first multipole 203. These two hexapole fields generate components of a second-order astigmatism (A2) and a third-order spherical aberration (C3) which are three-fold symmetric, respectively. The third-order spherical aberration (C3) can be controlled by adjusting an optical relationship between the first multipole 203 and the second multipole 206 and a magnitude of each multipole field to cancel the second-order astigmatism (A2) between the first multipole 203 and the second multipole 206.

The first multipole 203 and the second multipole 206 are not limited to being hexapole lenses including six magnetic poles and may be dodecapole lenses including 12 magnetic poles. That is, the number of magnetic poles may be changed to control an orientation of the formed hexapole field or to form another type of field.

Although the first multipole 203 and the second multipole 206 have a conjugate relationship with each other due to the transfer lens 204 and the transfer lens 205 can correct third-order or less aberrations such as a third-order spherical aberration 41 of the objective lens 105, it is difficult to independently control the fourth-order coma aberration (B4). Therefore, in Embodiment 1, first control for generating both the second-order coma aberration (B2) and the fourth-order coma aberration (B4) and second control for generating the B2 and the B4 at a generation ratio different from that of the first control are operated at an appropriate ratio to control the B4 together with the B2. That is, by operating both of the first control and the second control such that at least a part of the B2 generated in the first control is canceled by the B2 generated in the second control, the B4 can be substantially controlled alone. The first control is executed for, for example, the first deflector 202, and the second control is executed, for example, for the second deflector 207.

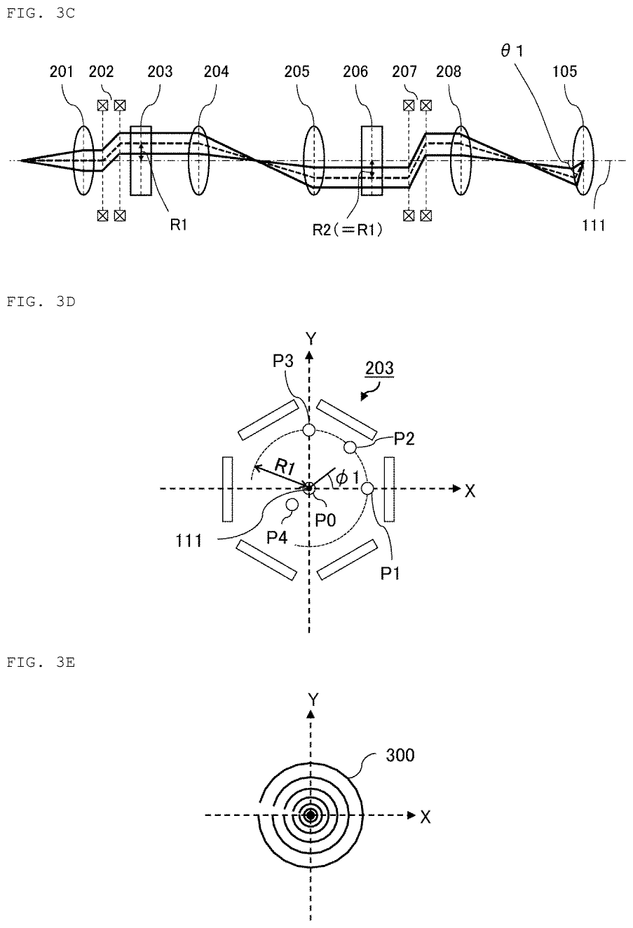

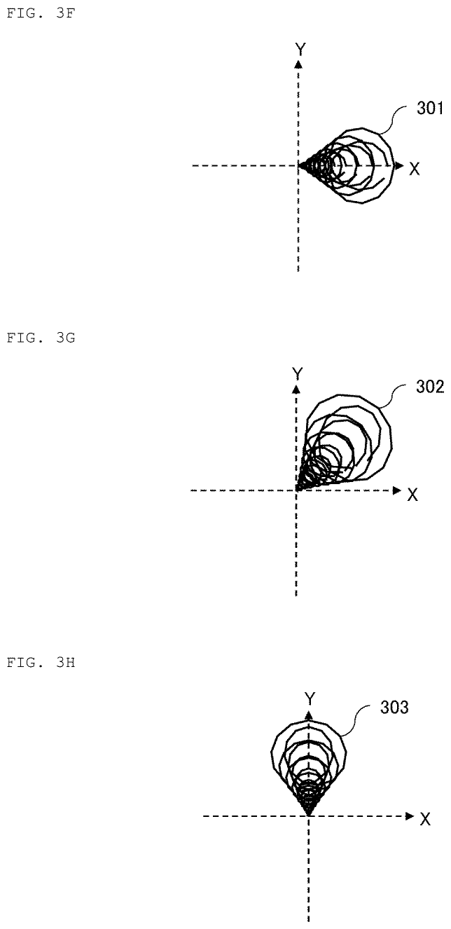

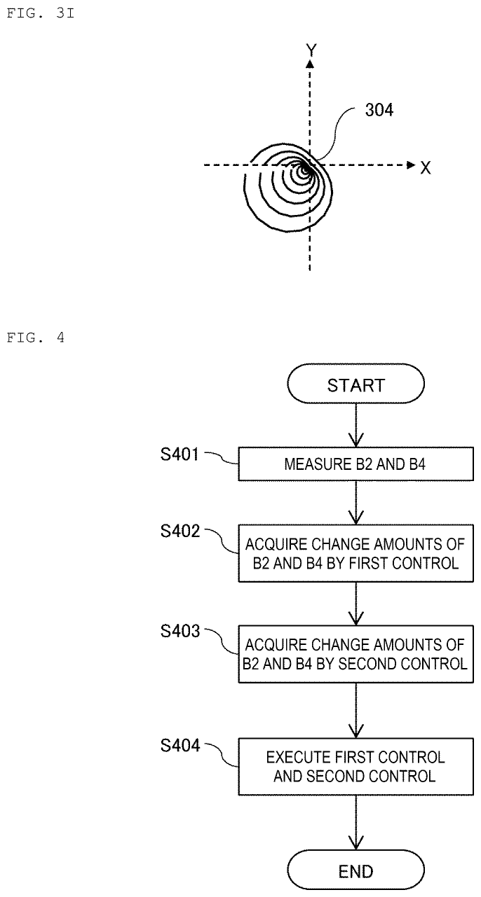

An operation of the first deflector 202 will be described with reference to FIG. 3A. The first deflector 202 is disposed on a side of the electron source 101 relative to the first multipole 203 and changes a distance R1 between the electron beam incident on the first multipole 203 and the axis 111 of the optical system. As the distance R1 between the electron beam incident on the first multipole 203 and the axis 111 of the optical system changes, a distance R2 between the electron beam incident on the second multipole 206 and the axis 111 of the optical system also changes. The electron beams incident on the first multipole 203 and the second multipole 206 are typically parallel to the axis 111 of the optical system, but may not be parallel to the axis 111 of the optical system. When the electron beam is not parallel to the axis 111 of the optical system, the distance R1 and the distance R2 are handled by being defined based on some reference, for example, on a thickness center plane of each multipole.

When the electron beam incident on the first multipole 203 moves away from the axis 111 of the optical system, a first-order astigmatism (A1), the second-order coma aberration (B2), and the fourth-order coma aberration (B4) are generated in the first multipole 203. Similarly, the first-order astigmatism (A1), the second-order coma aberration (B2), and the fourth-order coma aberration (B4) are also generated in the second multipole 206. When R1=R2, the A1 generated in the first multipole 203 is canceled by the A1 generated in the second multipole 206. The B2 generated in the first multipole 203 and the B2 generated in the second multipole 206 change according to a magnitude of the distance R1, the two B2 do not cancel each other, and a sum of the two B2 remains as a B2 component. The B4 generated in the first multipole 203 and the B4 generated in the second multipole 206 change according to a magnitude of the distance R1, the two B4 do not cancel each other, and a sum of the two B2 remains as a B4 component. That is, the B2 and the B4 are generated by an operation of the first deflector 202, and magnitudes of the B2 and the B4 are adjusted by the magnitude of the distance R1 controlled by the first deflector 202.

An operation of the second deflector 207 will be described with reference to FIG. 3B. The second deflector 207 is disposed between the second multipole 206 and the adjustment lens 208 and controls a slope θ1 between the electron beam incident on the objective lens 105 and the axis 111 of the optical system. When the electron beam incident on the objective lens 105 is tilted with respect to the axis 111 of the optical system, the second-order coma aberration (B2) and the fourth-order coma aberration (B4) are generated in the objective lens 105. Magnitudes of the B2 and the B4 generated in the objective lens 105 are adjusted by a magnitude of the slope θ1 controlled by the second deflector 207.

Control of the fourth-order coma aberration (B4) will be described with reference to FIG. 3C. A sum B2 tot of the B2 generated in the charged particle beam device when the first deflector 202 and the second deflector 207 operate is approximately represented by the following equation.

$$B2\_tot = K 1 \cdot R 1 + K 2 \cdot R 2 + K 3 \cdot θ 1 + B 2 \_init \qquad ( Formula 1 )$$

Here, K1·R1 is a B2 component generated by a change in the distance R1, K2·R2 is a B2 component generated by a change in the distance R2, K3·θ1 is a B2 component generated by a change in the slope θ1, and B2_init is a B2 component originally present in the charged particle beam device. K1, K2, and K3 are coefficients determined by a magnitude or a spatial shape of fields formed by the first multipole 203, the second multipole 206, and the objective lens 105.

A sum B4_tot of the B4 generated in the charged particle beam device when the first deflector 202 and the second deflector 207 operate is approximately represented by the following equation.

$$B4\_tot = K 4 \cdot R 1 + K 5 \cdot R 2 + K 6 \cdot θ 1 + B 4 \_init \qquad ( Formula 2 )$$

Here, K4·R1 is a B4 component generated by a change in the distance R1, K5·R2 is a B4 component generated by a change in the distance R2, K6·θ1 is a B4 component generated by a change in the slope θ1, and B4_init is a B4 component originally present in the charged particle beam device. K4, K5, and K6 are coefficients determined by a magnitude or a spatial shape of fields formed by the first multipole 203, the second multipole 206, and the objective lens 105.

When a ratio of the B2 and the B4 generated by the operation of the first deflector 202 is different from a ratio of the B2 and the B4 generated by the operation of the second deflector 207 and R1=R2, Formula 1 and Formula 2 can be solved as simultaneous equations of the R1 and the θ1. That is, by adjusting the R1 and the θ1, the B2 tot and the B4_tot can be set to desired values, for example, zero.

In the above example, a case is described in which an initial state before the aberration control is performed is a state in which the electron beam passes through the centers of the lenses and the multipoles, that is, a state in which the axis of the optical system and a trajectory of the electron beam coincide with each other. Meanwhile, in an actual device, it is assumed that control different from the above control is used in combination for an aberration other than the coma aberration. In such a case, in the initial state before the above control is performed, the distances (R1, R2) between the electron beams incident on the multipoles and the axis 111 of the optical system and the slope (θ1) may have a value other than 0. Even in such a case, the same effect can be obtained by defining the distance R1, the distance R2, and the slope θ1 in the above control by the relative distance from the trajectory of the electron beam and a displacement amount of the slope in the initial state before the above control is performed instead of the distance and the angle with respect to the axis 111 of the optical system. This is obvious from a fact that a change amount of the coma aberration approximately has a linear relationship with respect to a change in a position of the trajectory of the electron beam and a change in the slope and a f fact that addition and subtraction of aberration components can be performed between independent aberration components, as illustrated in (Formula 1).

A relationship between a position of the electron beam incident on the first multipole 203 and the second-order coma aberration (B2) generated in the first multipole 203 will be described with reference to FIGS. 3D to 3I. A relationship between a position of an electron beam incident on a multipole other than the first multipole 203 and the second-order coma aberration (B2) is the same as that in the case of the first multipole 203.

In FIG. 3D, in an XY plane orthogonal to the axis 111 of the optical system, P0, P1, P2, P3, and P4, which are center positions of the electron beams incident on the first multipole 203, are illustrated by white circles. The center position of the electron beam is illustrated by (X, Y) coordinates or coordinates (R1, φ1) of the distance R1 from the axis 111 of the optical system and an azimuth angle φ1 around the axis 111 of the optical system. The azimuth angle φ1 in FIG. 3D is a slope with respect to an X axis.

FIG. 3E illustrates a P0 pattern 300 that is a pattern formed on the specimen by the electron beam incident at the P0, which is the position of the axis 111 of the optical system. The electron beam incident on the first multipole 203 includes electrons that have different slopes and orientations and are emitted from the electron source, and the P0 pattern 300 is obtained by connecting positions where the electrons emitted at the same slope reach the specimen by lines. The P0 pattern 300 has an isotropic shape and indicates that the coma aberration are not generated.

FIG. 3F illustrates a P1 pattern 301 that is a pattern formed on the specimen by the electron beam incident at the P1, which is a position moved from the P0 in an orientation of the azimuth angle φ1=0°. The P1 pattern 301 has a shape extending in the orientation of the azimuth angle φ1=0° and indicates that the coma aberration is generated in the orientation of the azimuth angle φ1=0°.

FIG. 3G illustrates a P2 pattern 302 that is a pattern formed on the specimen by the electron beam incident at the P2, which is a position moved from the P0 in an orientation of the azimuth angle φ1=45°. The P2 pattern 302 has a shape extending in the orientation of the azimuth angle φ1=45° and indicates that the coma aberration is generated in the orientation of the azimuth angle φ1=45°.

FIG. 3H illustrates a P3 pattern 303 that is a pattern formed on the specimen by the electron beam incident at the P3, which is a position moved from the P0 in an orientation of the azimuth angle φ1=90°. The P3 pattern 303 has a shape extending in the orientation of the azimuth angle φ1=90° and indicates that the coma aberration is generated in the orientation of the azimuth angle φ1=90°.

The P1, P2, and P3 are positions where the azimuth angle φ1 is different but the distance R1 from the P0 is the same. The patterns corresponding to P1, P2, and P3 are different from one another in the extending orientation but have the same shape, and indicate that the coma aberrations having the same magnitude are generated in different orientations.

FIG. 3I illustrates a P4 pattern 304 that is a pattern formed on the specimen by the electron beam incident at the P4, which is a position moved from the P0 in an orientation of the azimuth angle φ1=225°. The azimuth angle φ1=225° is obtained by rotating the azimuth angle φ1=45° indicating a moving orientation from the P0 to the P2 by 180°, and a distance between the P0 and the P4 is less than a distance between the P0 and the P2. The P4 pattern 304 has a shape extending in the orientation of the azimuth angle φ1=225° and indicates that the coma aberration is generated in an orientation in which the azimuth angle φ1=45° is rotated by 180°. However, the P4 pattern 304 has a shape remaining near an origin of the XY plane compared to the P2 pattern 302 and indicates that the magnitude of the coma aberration is small.

As illustrated in FIGS. 3E to 3I, the coma aberration has two components of the magnitude and the orientation, the magnitude changes according to the distance from the axis 111 of the optical system to the position on which the electron beam is incident, and the orientation changes according to the azimuth angle of the position on which the electron beam is incident. That is, to change the magnitude of the coma aberration while maintaining the orientation in which the coma aberration is generated, it is sufficient that the distance from the axis 111 of the optical system is changed while maintaining the azimuth angle of the position on which the electron beam is incident. To change the orientation in which the coma aberration is generated while maintaining the magnitude of the coma aberration, it is sufficient that the azimuth angle of the position on which the electron beam is incident is changed while maintaining the distance between the position on which the electron beam is incident and the axis 111 of the optical system.

Since a magnetic field lens used in the optical system rotates the electron beam around the axis 111 of the optical system, a slope offset occurs between the orientation of the azimuth angle of the position on which the electron beam is incident and the orientation in which the coma aberration is generated. The slope offset changes according to conditions of the optical system and an excitation amount of the magnetic field lens.

In FIGS. 3D to 3I, a case in which incident positions of the electron beam is moved from the position of the axis 111 of the optical system has been described, but the relationship between the change of the incident position and the generated coma aberration is the same even when the electron beam is moved from any position.

The coma aberration having the two components of the magnitude and the orientation may be handled in a complex plane in which a real axis and an imaginary axis are orthogonal to each other. When the coma aberration is handled in the complex plane, the distance between the incident position of the electron beam and the axis 111 of the optical system and the azimuth angle of the incident position of the electron beam are also handled in the complex plane, and a real component and an imaginary component of the coma aberration change corresponding to a real component and an imaginary component of the incident position of the electron beam.

When the slope θ1 of the electron beam incident on the objective lens 105 is controlled as illustrated in FIG. 3B, the magnitude of the coma aberration generated in the objective lens 105 changes according to the magnitude of the slope θ1, and the orientation in which the coma aberration is generated changes according to the azimuth angle of the electron beam incident on the objective lens 105. When the coma aberration generated by the control of the slope θ1 is handled in the complex plane, the magnitude of the slope θ1 and the azimuth angle of the incident electron beam are also handled in the complex plane, and the real component and the imaginary component of the coma aberration change corresponding to the magnitude of the slope θ1 and the real component and the imaginary component of the azimuth angle of the incident electron beam.

As described above, similarly to the control of the magnitude of the coma aberration by the adjustment of the distance R1 and the slope θ1, the orientation in which the coma aberration is generated can be controlled by adjusting the azimuth angle of the electron beam incident on the first multipole 203 or the objective lens 105.

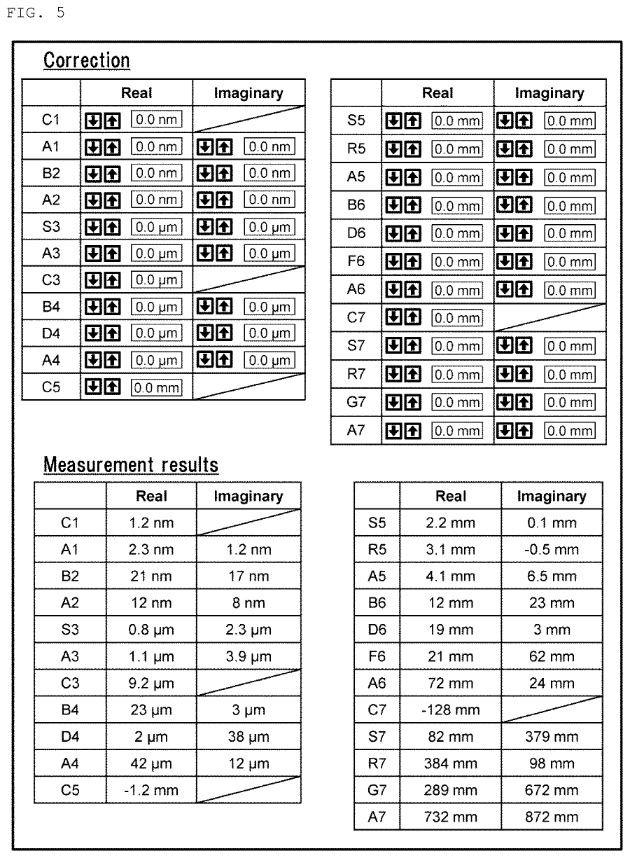

An example of a flow of processing according to Embodiment 1 will be described for each step with reference to FIG. 4.

### (S401)

The control unit 110 measures the second-order coma aberration (B2) and the fourth-order coma aberration (B4) using the observation image or the pattern. The pattern used to measure the B2 and the B4 is, for example, a projection pattern such as a Ronchigram. The measured B2 and B4 correspond to B2_init in (Formula 1) and B4_init in (Formula 2).

### (S402)

The control unit 110 acquires change amounts of the B2 and the B4 by the first control executed on the first deflector 202. Specifically, B2_0 and B4_0 that are the B2 and the B4 when the distance R1 is R1_0 and B2_0+ΔB2 and B4_0+ΔB4 that are the B2 and the B4 when the distance R1 is R1_0+ΔR1 are measured, and ΔB2/ΔR1 and ΔB4/ΔR1 are calculated based on the measurement values. ΔB2/ΔR1 approximately corresponds to K1+K2 in (Formula 1), and ΔB4/ΔR1 approximately corresponds to coefficients K4+K5 in (Formula 2).

### (S403)

The control unit 110 acquires change amounts of the B2 and the B4 by the second control executed on the second deflector 207. Specifically, the B2 and the B4 in the case of the slope θ1 and B2+ΔB2 and B4+ΔB4 in a case of the slope θ1+Δθ1 are measured, and ΔB2/θ1 and ΔB4/Δθ1 are calculated based on the measurement values. ΔB2/Δθ1 corresponds to K3 in (Formula 1), and ΔB4/Δθ1 corresponds to K6 in (Formula 2).

### (S404)

The control unit 110 executes, based on the values measured in S401 and the values acquired in S402 and S403, the first control and the second control such that the second-order coma aberration (B2) and the fourth-order coma aberration (B4) become desired values. That is, the first control and the second control are executed by solving (Formula 1) and (Formula 2) for the R1 and the 01. For example, the desired values of the B2 and the B4 are input by an operator from an aberration adjustment screen displayed on the control unit 110.

An example of the aberration adjustment screen will be described with reference to FIG. 5. In the screen illustrated in FIG. 5, a correction value of each aberration is set in the upper stage, and a measurement value of each aberration is displayed in the lower stage. The correction value of each aberration is set by using increase and decrease buttons indicated by an up arrow and a down arrow and a numerical value input box. A relative value or an absolute value of the aberration is input to the numerical value input box. Since aberrations in addition to spherical aberrations C1, C3, C5, and C7 have two components in a Real (X) orientation and an Imaginary (Y) orientation, the aberrations each have four buttons including increase and decrease buttons for Real and increase and decrease buttons for Imaginary.

By the flow of the processing described with reference to FIG. 4, the second-order coma aberration (B2) can be set to a desired value, and the fourth-order coma aberration (B4) can be controlled to a desired value. Since a total amount of the charged particle beams illuminated to the specimen can be increased by the control on B4, generation efficiency of the fluorescent X-rays detected in an STEM-EDX analysis can be improved, and the element distribution image can be generated in a short time. The configuration of the aberration corrector is not limited to FIG. 2A.

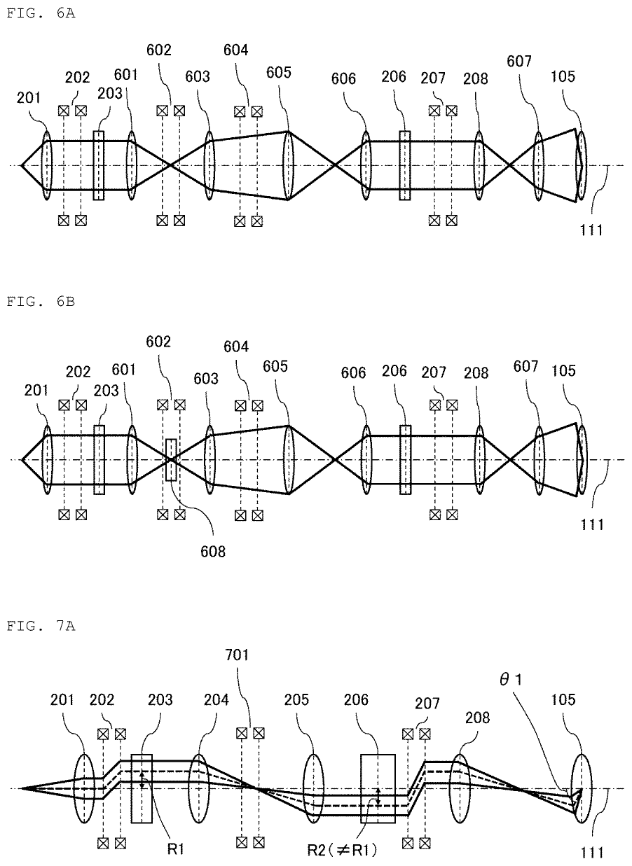

Other examples of the aberration corrector will be described with reference to FIGS. 6A and 6B. In FIG. 6A, the two transfer lenses 204 and 205 in FIG. 2A are replaced with four transfer lenses 601, 603, 605, and 606 and deflectors 602 and 604, and an adjustment lens 607 is added. In FIG. 6B, a multipole 608 is added relative to FIG. 6A. The same applies to FIGS. 6A and 6B except that an orientation of a multipole field formed in the second multipole 206 changes with respect to the orientation in FIG. 2. That is, in any of the configurations of FIGS. 6A and 6B, a second-order coma aberration (B2) can be set to a desired value, and a fourth-order coma aberration (B4) can be controlled to a desired value.

### Embodiment 2

In Embodiment 1, the fourth-order coma aberration (B4) is controlled to a desired value. In Embodiment 2, to further reduce a diameter of a charged particle beam illuminated to a specimen, controlling a sixth-order coma aberration (B6) together with a fourth-order coma aberration (B4) will be described. Since a part of configurations and functions described in Embodiment 1 can be applied in Embodiment 2, the same configurations and functions are denoted by the same reference numerals, and description thereof will be omitted.

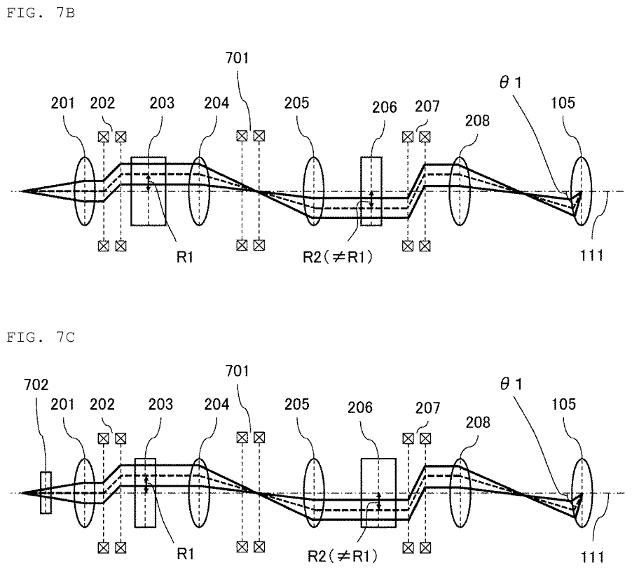

An example of a configuration for controlling the sixth-order coma aberration (B6) will be described with reference to FIG. 7A. In FIG. 7A, a third deflector 701 is added to the configuration in FIG. 2A, and a thickness of the second multipole 206 is different from a thickness of the first multipole 203.

The third deflector 701 is disposed between the transfer lens 204 and the transfer lens 205 and controls the distance R2 between the electron beam incident on the second multipole 206 and the axis 111 of the optical system independently of the distance R1 between the electron beam incident on the first multipole 203 and the axis 111 of the optical system. The second multipole 206 forms a quadrupole field superimposed on a hexapole field together with the hexapole field.

The total B2 tot of the B2 and the total B4_tot of the B4 generated in the charged particle beam device when the third deflector 701 operates in addition to the first deflector 202 and the second deflector 207 are as (Formula 1) and (Formula 2), respectively, and a total B6 tot of the sixth-order coma aberration (B6) is as the following equation.

$$B6\_tot = K 7 \cdot R 1 + K 8 \cdot R 2 + K 9 \cdot θ 1 + B 6 \_init \qquad ( Formula 3 )$$

Here, K7·R1 is a B6 component generated by a change in the distance R1, K8·R2 is a B6 component generated by a change in the distance R2, K9·θ1 is a B6 component generated by a change in the slope θ1, and B6_init is a B6 component originally present in the charged particle beam device. K7, K8, and K9 are coefficients determined by a magnitude or a spatial shape of fields formed by the first multipole 203, the second multipole 206, and the objective lens 105. A spatial shape of a field in which a multipole is formed is controlled by a thickness of the multipole.

When the thickness of the first multipole 203 and the thickness of the second multipole 206 are different from each other, K1 and K2 in (Formula 1) have different values, K4 and K5 in (Formula 2) have different values, and K7 and K8 in (Formula 3) have different values even under the condition that the second-order astigmatism (A2) is canceled between the two multipoles. With K1+K2, K4+K5, and K7+K8, (Formula 1), (Formula 2), and (Formula 3) can be solved as simultaneous equations of the R1, the R2, and the θ1. That is, by adjusting the R1, the R2, and the θ1, the B2 tot, the B4_tot, and the B6 tot can be set to desired values, for example, zero. Each of the coefficients K1 to K9 is calculated based on the change amounts of the B2, the B4, and the B6 caused by the control executed for each of the first deflector 202, the second deflector 207, and the third deflector 701. B6_init is measured together with B2_init and B4_init.

However, when the thickness of the first multipole 203 and the thickness of the second multipole 206 are different from each other, the first-order astigmatism (A1) generated in the first multipole 203 cannot be canceled by the A1 generated in the second multipole 206 under a condition that the second-order astigmatism (A2) is canceled therebetween. Therefore, in Embodiment 2, the quadrupole field is superimposed on the hexapole field formed by the second multipole 206, and a magnitude of the superimposed quadrupole field is controlled to cancel the remaining an A1 component.

With the configuration described with reference to FIG. 7A, the sixth-order coma aberration (B6) can be controlled together with the fourth-order coma aberration (B4). Since the total amount of the charged particle beam illuminated to the specimen can be further increased by the control of the B6, the element distribution image can be generated in a shorter time.

The configuration for controlling the sixth-order coma aberration (B6) is not limited to that in FIG. 7A and may be configurations illustrated in FIG. 7B and FIG. 7C. In FIG. 7B, the thickness of the first multipole 203 and the thickness of the second multipole 206 are different from each other, and the quadrupole field is superimposed on the hexapole field formed by the first multipole 203. In FIG. 7C, the thickness of the first multipole 203 and the thickness of the second multipole 206 are different from each other, and the third multipole 702 disposed at a position optically different from that of the first multipole 203 and that of the second multipole 206 forms at least one of a quadrupole field and a dipole field. As in FIG. 7A, the third deflector 701 controls the distance R2 between the electron beam incident on the second multipole 206 and the axis 111 of the optical system independently of the distance R1 between the electron beam incident on the first multipole 203 and the axis 111 of the optical system.

Similarly to the description of Embodiment 1, a case is described in which an initial state before the aberration control is performed in the above control in the present embodiment is a state in which the electron beams pass through centers of the lenses and the multipoles, that is, a state in which the axis of the optical system and the trajectory of the electron beam coincide with each other. When the initial state before the above control is performed is different from the initial state described above, the same effect can be obtained by defining the distance R1, the distance R2, and the slope θ1 in the above control by the relative distance from the trajectory of the electron beam and a displacement amount of the slope in the initial state before the above control is performed instead of the distance and the angle with respect to the axis 111 of the optical system.

Also in the configurations of FIGS. 7B and 7C, by solving (Formula 1), (Formula 2), and (Formula 3) as simultaneous equations of the R1, the R2, and the θ1 and adjusting the R1, the R2, and the θ1, B2_tot, B4_tot, and B6_tot can be set to desired values, for example, zero. The first-order astigmatism (A1) caused by R2+R1 is canceled by controlling the magnitude of at least one of the quadrupole field and the dipole field formed by the third multipole 702.

The embodiments of the charged particle beam device according to the invention have been described above. The charged particle beam device according to the invention is not limited to the above embodiments and can be embodied by modifying components without departing from the gist of the invention. A plurality of components disclosed in the above embodiments may be combined appropriately. A part of components may be deleted from all components disclosed in the above embodiments.

### REFERENCE SIGNS LIST

100: lens body
101: electron source
102: condenser lens
103: condenser lens
104: aperture
105: objective lens
106: specimen
107: intermediate lens
108: projection lens
109: detector
110: control unit
111: axis of optical system
120: aberration corrector
201: adjustment lens
202: first deflector
203: first multipole
204: transfer lens
205: transfer lens
206: second multipole
207: second deflector
208: adjustment lens
300: P0 pattern
301: P1 pattern
302: P2 pattern
303: P3 pattern
304: P4 pattern
601: transfer lens
602: deflector
603: transfer lens
604: deflector
605: transfer lens
606: transfer lens
607: adjustment lens
608: multipole
701: third deflector
702: third multipole

1. An aberration corrector in which a transfer lens is disposed between a first multipole and a second multipole, each of the first multipole and the second multipole forming a multipole field including a component of a hexapole field, the aberration corrector comprising:
a first deflector configured to control at least one of a distance between a charged particle beam incident on the first multipole and an axis of an optical system and an azimuth angle of the charged particle beam incident on the first multipole;
a second deflector configured to control at least one of a slope between a charged particle beam incident on an objective lens and the axis of the optical system and an azimuth angle of the charged particle beam incident on the objective lens; and
a control unit configured to control the first deflector and the second deflector, wherein
the control unit executes first control executed on the first deflector and second control executed on the second deflector such that at least a part of a second-order coma aberration caused by the first control is canceled by a second-order coma aberration caused by the second control.

2. The aberration corrector according to claim 1, wherein
the control unit executes the first control and the second control based on a measurement value of a second-order coma aberration, a change in the second-order coma aberration caused by the first control, and a change in the second-order coma aberration caused by the second control.

3. The aberration corrector according to claim 2, wherein
the control unit measures a second-order coma aberration by using an observation image or a projection pattern.

4. A charged particle beam device for generating an observation image of a specimen by illuminating the specimen with a charged particle beam, the charged particle beam device comprising:
the aberration corrector according to claim 1.

5. The charged particle beam device according to claim 4, further comprising:
a display unit configured to display at least one of a magnitude and an orientation of a measured aberration.

6. An aberration corrector in which a transfer lens is disposed between a first multipole and a second multipole, each of the first multipole and the second multipole forming a multipole field including a component of a hexapole field, the aberration corrector comprising:
a first deflector configured to control at least one of a distance between a charged particle beam incident on the first multipole and an axis of an optical system and an azimuth angle of the charged particle beam incident on the first multipole;
a second deflector configured to control at least one of a slope between a charged particle beam incident on an objective lens and the axis of the optical system and an azimuth angle of the charged particle beam incident on the objective lens;
a third deflector configured to control at least one of a distance between a charged particle beam incident on the second multipole and the axis of the optical system and an azimuth angle of the charged particle beam incident on the second multipole; and
a control unit configured to control the first deflector, the second deflector, and the third deflector, wherein
the control unit executes first control executed on the first deflector, second control executed on the second deflector, and third control executed on the third deflector such that at least a part of coma aberrations caused by at least two of the first control, the second control, and the third control is canceled.

7. The aberration corrector according to claim 6, wherein
a magnitude of the multipole field formed by the first multipole is different from a magnitude of the multipole field formed by the second multipole,
or a thickness of the first multipole is different from a thickness of the second multipole.

8. The aberration corrector according to claim 6, wherein
the control unit superimposes a quadrupole field on at least one of the first multipole and the second multipole and cancels at least a part of a first-order astigmatism generated by at least one of the first control, the second control, and the third control by the quadrupole field.

9. The aberration corrector according to claim 6, further comprising:
a third multipole configured to form at least one of a quadrupole field and a dipole field, wherein
the control unit cancels at least a part of a first-order astigmatism generated by at least one of the first control, the second control, and the third control by at least one of the quadrupole field and the dipole field.

10. The aberration corrector according to claim 6, wherein
the control unit executes at least two of the first control, the second control, and the third control based on a change in coma aberrations caused by at least two of the first control, the second control, and the third control.

11. The aberration corrector according to claim 6, wherein
the control unit measures a coma aberration by using an observation image or a projection pattern.

12. A charged particle beam device for generating an observation image of a specimen by illuminating the specimen with a charged particle beam, the charged particle beam device comprising:
the aberration corrector according to claim 6.

13. The charged particle beam device according to claim 12, further comprising:
a display unit configured to display at least one of a magnitude and an orientation of a measured aberration.

14. A control method for controlling an aberration corrector in which a transfer lens is disposed between a first multipole and a second multipole, the control method comprising:
executing first control executed on a first deflector configured to control at least one of a distance between a charged particle beam incident on the first multipole and an axis of an optical system and an azimuth angle of the charged particle beam incident on the first multipole and second control executed on a second deflector configured to control at least one of a slope between a charged particle beam incident on an objective lens and the axis of the optical system and an azimuth angle of the charged particle beam incident on the objective lens such that at least a part of a second-order coma aberration caused by the first control is canceled by a second-order coma aberration caused by the second control.

15. A control method for controlling an aberration corrector in which a transfer lens is disposed between a first multipole and a second multipole, the control method comprising:
executing first control executed on a first deflector configured to control at least one of a distance between a charged particle beam incident on the first multipole and an axis of an optical system and an azimuth angle of the charged particle beam incident on the first multipole,
second control executed by a second deflector configured to control at least one of a slope between a charged particle beam incident on an objective lens and the axis of the optical system and an azimuth angle of the charged particle beam incident on the objective lens, and
third control executed by a third deflector configured to control at least one of a distance between a charged particle beam incident on the second multipole and the axis of the optical system and an azimuth angle of the charged particle beam incident on the second multipole such that at least a part of coma aberrations generated by at least two of the first control, the second control, and the third control is canceled.
